(19) United States
(12) Patent Application Publication
(10) Pub. No.: US 2010/0301494 A1
(43) Pub. Date: Dec. 2, 2010

(54) RE-ESTABLISHING A HYDROPHOBIC SURFACE OF SENSITIVE LOW-K DIELECTRICS IN MICROSTRUCTURE DEVICES

(76) Inventors: Matthias Schaller, Moritzburg (DE); Thomas Oszinda, Dresden (DE); Susanne Leppack, Dresden (DE); Daniel Fischer, Dresden (DE)

Correspondence Address: WILLIAMS, MORGAN & AMERSON, 10333 RICHMOND, SUITE 1100, HOUSTON, TX, 77042, US

(21) Appl. No.: 12/786,117

(22) Filed: May 24, 2010

(30) Foreign Application Priority Data
May 29, 2009 (DE) 10 2009 023 378.4

(51) Int. Cl. H01L 23/48; H01L 21/71; H01L 21/02

(52) U.S. Cl. 257/774; 438/700; 438/765; 257/E21.536; 257/E21.002; 257/E23.011

(57) ABSTRACT

Silicon oxide based low-k dielectric materials may be provided with a hydrophobic low-k surface area, even after exposure to a reactive process ambient, by performing a surface treatment on the basis of hexamethylcyclotrisilazane and/or octamethylcyclotetrasilazane. In addition to the surface treatment, a polymerization may be initiated on the basis of a hydrophobic surface nature of the silicon-based dielectric material, thereby increasing the chemical stability during the further processing.

### BACKGROUND OF THE INVENTION

1. Field of the Invention

Generally, the present disclosure relates to microstructures, such as advanced integrated circuits, and, more particularly, to material systems including silicon oxide based dielectrics having a low dielectric constant.

2. Description of the Related Art

In the fabrication of modern microstructures, such as integrated circuits, there is a continuous drive to improve performance in view of operational behavior and diversity of functions integrated in a single microstructure device. For this purpose, there is an ongoing demand to steadily reduce the feature sizes of microstructure elements, thereby enhancing the functionality of these structures. For instance, in modern integrated circuits, minimum feature sizes, such as the channel length of field effect transistors, have reached the deep submicron range, thereby increasing performance of these circuits in terms of speed and/or power consumption and/or diversity of functions. As the size of individual circuit elements is reduced with every new circuit generation, thereby improving, for example, the switching speed of the transistor elements, frequently new materials may be required in order to not unduly offset any advantages that may be achieved by reducing the feature sizes of the individual components of microstructure devices, such as circuit elements and the like. For instance, upon shrinking the critical dimensions of transistors, thereby increasing the density of individual circuit elements, the available floor space for interconnect lines electrically connecting the individual circuit elements is also decreased. Consequently, the dimensions of these interconnect lines are also reduced to compensate for a reduced amount of available floor space and for an increased number of circuit elements provided per unit die area as typically two or more interconnections are required for each individual circuit element. Thus, a plurality of stacked “wiring” layers, also referred to as metallization layers, is usually provided, wherein individual metal lines of one metallization layer are connected to individual metal lines of an overlying or underlying metallization layer by so-called vias. Despite the provision of a plurality of metallization layers, reduced dimensions of the interconnect lines are necessary to comply with the enormous complexity of, for instance, modern CPUs, memory chips, ASICs (application specific ICs) and the like.

Advanced integrated circuits, including transistor elements having a critical dimension of 0.05 μm and even less, may, therefore, typically be operated at significantly increased current densities of up to several kA per cm² in the individual interconnect structures, despite the provision of a relatively large number of metallization layers, owing to the increased number of circuit elements per unit area. Consequently, well-established materials, such as aluminum, are being replaced by copper and copper alloys, i.e., materials with a significantly lower electrical resistivity and improved resistance to electromigration even at considerably higher current densities compared to aluminum.

The introduction of copper into the fabrication of microstructures and integrated circuits comes along with a plurality of severe problems residing in copper's characteristics to readily diffuse in silicon dioxide and other dielectric materials, as well as the fact that copper may not be readily patterned on the basis of well-established plasma assisted etch recipes. For example, based on conventional plasma assisted etch processes, copper may not substantially form any volatile etch byproducts such that the patterning of a continuous copper layer with a thickness that is appropriate for forming metal lines may not be compatible with presently available etch strategies. Consequently, the so-called damascene or inlaid process technique may typically be applied in which a dielectric material may be formed first and may be subsequently patterned in order to receive trenches and via openings, which may be subsequently filled with the copper-based material by using, for instance, electrochemical deposition techniques. Moreover, copper has a pronounced diffusivity in a plurality of dielectric materials, such as silicon dioxide based materials, which are frequently used as interlayer dielectric materials, thereby requiring the deposition of appropriate barrier materials prior to actually filling corresponding trenches and via openings with the copper-based material. Although silicon nitride and related materials may have excellent diffusion blocking capabilities, using silicon nitride as an interlayer dielectric material is less than desirable due to the moderately high dielectric constant, which may result in a non-acceptable performance degradation of the metallization system. Similarly, in sophisticated applications, the reduced distance of metal lines may require a new type of dielectric material in order to reduce signal propagation delay, cross-talking and the like, which are typically associated with a moderately high capacitive coupling between neighboring metal lines. For this reason, so-called low-k dielectric materials are increasingly being employed, which may generally have a dielectric constant of 3.0 or less, thereby maintaining the parasitic capacitance values in the metallization system at an acceptable level, even for the overall reduced dimensions in sophisticated applications.

Since silicon dioxide has been widely used in the fabrication of microstructure devices and integrated circuits, a plurality of modified silicon oxide based materials have been developed in recent years in order to provide dielectric materials with a reduced dielectric constant on the basis of precursor materials and process techniques that may be compatible with the overall manufacturing process for microstructure devices and integrated circuits. For instance, silicon oxide materials with a moderately high amount of carbon and hydrogen, for instance referred to as SICOH materials, have become a frequently used low-k dielectric material, which may be formed on the basis of a plurality of precursor materials, such as silane-based materials, in combination with ammonium and the like, which may be applied by chemical vapor deposition (CVD) techniques and the like. In other cases, spin-on glass (SOG) materials may be modified so as to contain a desired high fraction of carbon and hydrogen, thereby providing the desired low dielectric constant.

In still other sophisticated approaches, the dielectric constant of these materials may be even further reduced by further reducing the overall density of these materials, which may be accomplished by incorporating a plurality of cavities of nano dimensions, also referred to as pores, which may represent gas-filled or air-filled cavities within the dielectric material, thereby obtaining a desired reduced dielectric constant. Although the permittivity of these dielectric materials may be reduced by incorporating carbon and forming a corresponding porous structure, which may result in a very increased surface area at interface regions connecting to other materials, the overall mechanical and chemical characteristics of these low-k and ultra low-k (ULK) materials may also be significantly altered and may result in additional problems during the processing of these materials.

For example, as discussed above, the dielectric material may typically have to be provided first and may be patterned so as to receive trenches and via openings, which may require the exposure of the sensitive low-k dielectric materials to various reactive process atmospheres. That is, the patterning of the dielectric material may typically involve the formation of an etch mask based on a resist material and the like followed by plasma assisted etch processes in order to form the trenches and via openings corresponding to the design rules of the device under consideration. Thereafter, usually, cleaning processes may have to be performed in order to remove contaminants and other etch byproducts prior to depositing materials, such as conductive barrier materials and the like. Consequently, at least certain surface areas of the sensitive low-k dielectric materials may be exposed to plasma assisted processes, such as resist strip processes performed on the basis of an oxygen plasma, wet chemical reagents in the form of acids, aggressive bases, alcohols and the like, which may thus result in a certain degree of surface modification or damage. For instance, the low-k dielectric materials may typically be provided with a hydrophobic surface in order to avoid the incorporation of OH groups and the like, which may represent polarizable groups that may therefore respond to an electrical field, thereby significantly increasing the resulting permittivity of the surface portion of the material. Upon exposure of the hydrophobic surface to reactive atmospheres, such as plasma, aggressive wet chemical reagents and the like, the hydrocarbon groups of the hydrophobic surface area may be replaced by other groups and may finally result in the creation of silanol groups, which result in a significant increase of the dielectric constant at the surface area of the dielectric material. This surface modification or damaging may result in a significant modification of the dielectric behavior of the metallization system which may not be compatible with the performance requirements of sophisticated integrated circuits. Hence, great efforts are being made in providing silicon oxide based low-k dielectric materials while avoiding or at least reducing the surface modification during the patterning of the sensitive dielectric material. To this end, it has been suggested to selectively remove a damaged surface portion of the low-k dielectric materials on the basis of appropriate etch strategies so as to re-establish the desired hydrophobic surface characteristics. In this case, appropriate etch recipes may have to be applied without exposure of the resulting structure to any further aggressive process ambient in order to maintain the hydrophobic nature of the surface until the deposition of a conductive barrier material and the like. Additionally, the material removal may result in an increase of the critical dimensions of the metal lines and vias, which may be undesirable in view of enhanced packing density, since the increased critical dimension may have to be taken into consideration when designing the metallization system under consideration.

In other approaches, the hydrophobic nature may be re-established by performing a surface treatment after exposing the low-k dielectric material to the aggressive process ambient, which may be accomplished by using specific compounds. For example, U.S. Pat. No. 7,029,826 discloses a surface treatment of porous silica materials by exposing the damaged surface area to one or more compounds having the formula as follows: R₃SINHSIR₃, RXSICLY, RXCI(OH)Y, R₃SIOSIR₃, RXSI(OR)Y, MPSI(HO)_{4-P}, RXSI(OCOCH₃) YR, and combinations thereof, wherein X is an integer ranging from 1-3, Y is an integer ranging from 1-3 such that Y=4-X, P is an integer ranging from 2-3, each R is selected from hydrogen and a hydrophobic organic moiety, each M is an independently selected hydrophobic organic moiety, and R and M can be the same or different. In other examples disclosed therein, the surface modification composition includes organic compounds of silane, hexamethyldisilazane, nonamethyltrisilazane and other silanol-based compounds.

Although a surface treatment with chemical reagents as specified in this document may provide enhanced hydrophobic surface conditions of nanoporous silica dielectric materials, there is still room for further improvement, for instance with respect to providing other appropriate surface modification reagents and further enhancing the surface conditions of sensitive silicon oxide based dielectric materials during the further processing.

The present disclosure is directed to various methods and devices that may avoid, or at least reduce, the effects of one or more of the problems identified above.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

Generally, the present disclosure relates to process techniques and devices, such as microstructure devices, in which silicon oxide based dielectric materials may be provided with a low dielectric constant, for instance, by incorporating a moderately high carbon fraction and possibly by providing a porous structure, wherein the surface may have a hydrophobic nature, in particular at an interface that may be in contact with metal-containing materials. For this purpose, in some illustrative aspects disclosed herein, critical surface portions of the low-k dielectric material may be treated on the basis of hexamethylcyclotrisilazane and/or on the basis of octamethylcyclotetrasilazane in order to re-establish the hydrophobic nature of exposed surface portions, even after the contact with an aggressive process ambient, such as a plasma ambient, a wet chemical ambient and the like. In other illustrative aspects disclosed herein, in addition or alternatively to treating exposed surface portions of the low-k dielectric material on the basis of the above-specified reagents, a chemical reagent may be supplied in order to initiate the creation of cross-linkings of surface molecules, for instance in the form of a di-merization or a polymerization, thereby imparting superior chemical stability to the surface area of the low-k dielectric material, which may be advantageous during the further processing of the low-k dielectric material, for instance, when forming sophisticated microstructure devices. In some illustrative embodiments disclosed herein, the initiation of the cross-linking of the surface area may be performed during or after a treatment on the basis of the reagents specified above.

One illustrative method disclosed herein relates to forming a low-k dielectric material above a substrate. The method comprises forming a silicon and oxygen containing dielectric material above the substrate. Furthermore, the method comprises performing a surface treatment on at least a portion of the surface of the silicon and oxygen containing dielectric material on the basis of at least one of hexamethylcyclotrisilazane and octamethylcyclotetrasilazane so as to obtain a dielectric constant of approximately 3.0 or less, at least at the portion of the silicon and oxygen containing dielectric material.

A further illustrative method disclosed herein relates to forming a low-k dielectric material in a microstructure device. The method comprises forming a silicon and oxygen containing dielectric material above a substrate so as to have a dielectric constant of approximately 3.0 or less, wherein at least a portion of a surface of the silicon and oxygen containing dielectric material represents a hydrophobic surface. The method further comprises performing a treatment for forming cross-links in the hydrophobic surface by supplying one or more chemical reagents to the hydrophobic surface.

One illustrative microstructure device comprises a low-k dielectric material formed above a substrate, wherein the low-k dielectric material comprises silicon and oxygen and a hydrophobic interface portion with a polymerized surface structure.

### BRIEF DESCRIPTION OF THE DRAWINGS

The disclosure may be understood by reference to the following description taken in conjunction with the accompanying drawings, in which like reference numerals identify like elements, and in which:

FIG. 1a schematically illustrates a cross-sectional view of a substrate, such as a substrate for forming microstructure devices and the like, on which is formed a silicon oxide based low-k dielectric material having a hydrophobic surface;

FIGS. 1b-1c schematically illustrate the device when exposed to a reactive process ambient, such as a plasma ambient, thereby causing polarized molecule groups to be bonded to the surface;

FIG. 1d schematically illustrates the device when exposed to a process ambient for performing a surface treatment on the basis of hexamethylcyclotrisilazane in order to provide a hydrophobic surface area, according to illustrative embodiments;

FIG. 1e schematically illustrates the device according to further illustrative embodiments in which an exposed surface area of a silicon oxide based low-k dielectric material may be treated on the basis of octamethylcyclotetrasilazane in order to provide a hydrophobic surface;

FIGS. 1f-1h schematically illustrate cross-sectional views of the device according to still further illustrative embodiments in which, additionally or alternatively to performing a treatment according to FIGS. 1d-1e, a cross-linking of surface molecules may be accomplished by supplying a chemical providing cross-linking capabilities, according to further illustrative embodiments; and

FIGS. 2a-2c schematically illustrate cross-sectional views of a microstructure device, such as a semiconductor device, during various manufacturing stages in forming a patterned low-k dielectric material, for instance a dielectric material for a metallization system of a semiconductor device on the basis of process techniques as described with reference to FIGS. 1a-1h, according to still further illustrative embodiments.

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION

Various illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present subject matter will now be described with reference to the attached figures. Various structures, systems and devices are schematically depicted in the drawings for purposes of explanation only and so as to not obscure the present disclosure with details that are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

Generally, the present disclosure provides process techniques and microstructure devices in which superior characteristics of a silicon oxide based low-k dielectric material may be obtained by performing a surface treatment based on hexamethylcyclotrisilazane and/or octamethylcyclotetrasilazane, possibly in combination with a treatment on the basis of a chemical that provides the capability of forming cross-links in order to obtain enhanced chemical stability during the further processing of the low-k dielectric material. It should be appreciated that the present disclosure may be very advantageous in the context of manufacturing strategies used in sophisticated microelectronic fabrication techniques in which silicon oxide based low-k dielectric materials, for instance in the form of porous materials, may provide superior performance with respect to parasitic capacitance and the like. As previously explained, in many of these sophisticated fabrication techniques, a low-k dielectric material has to be exposed to reactive process atmospheres, for instance for patterning or otherwise treating the low-k dielectric material, which may result in the formation of silanol groups, which in turn may result in a significant increase of the dielectric constant of a surface portion of the silicon oxide based material, thereby increasing the overall permittivity of the entire material layer. Consequently, based on a surface treatment using the above-specified silazane derivatives, a desired hydrophobic surface structure and thus a low-k value may be re-established without requiring significant modifications of the overall process flow.

In other cases, the exposed surface of a silicon oxide based dielectric material as deposited may be treated in order to further enhance the hydrophobic nature of the exposed surface, without actually exposing the device to a highly reactive process ambient. For example, an increased degree of flexibility with respect to selecting an appropriate deposition technique for silicon oxide based materials may be provided, for instance, in view of using plasma-based deposition techniques, since a desired hydrophobic surface structure may be established or may be enhanced by performing a corresponding surface treatment.

In other illustrative embodiments disclosed herein, the surface characteristics of a silicon oxide based dielectric material may be enhanced in view of superior chemical stability by initiating a cross-linking, such as a di-merization or a polymerization, while still suppressing the presence of unwanted silanol groups, thereby providing a low-k surface area with superior chemical stability, which may be highly advantageous during the further processing of the silicon oxide based dielectric material. For example, the exposure to the ambient atmosphere in a clean room may be less critical due to the superior stability of the cross-linked or polymerized surface structure, which may result in superior flexibility in scheduling the overall process flow. It should be appreciated that a lot of chemicals may be used, which provide the possibility of linking each other, wherein well-established species may be used, such as silane and any derivatives thereof, in combination with an appropriate functional group, such as a phenyl group or a vinyl group and the like. In some illustrative embodiments the corresponding cross-linking may be initiated during or after a corresponding surface treatment, which may be accomplished in the same process ambient, thereby providing a highly efficient overall process flow.

It should be appreciated that the term low-k relates to the dielectric constant of a dielectric material with a value of 3.0 or less. Generally, the dielectric constant of a material can be determined by various techniques, such as using the dielectric material as the dielectric of a capacitor having a well-defined configuration, such as general shape and configuration, such as a parallel plate configuration, and the like, the area of electrodes, the distance of the electrodes, and the like. For example, a parallel plate capacitor may be readily formed on the basis of typical substrates as used for semiconductor fabrication and one or many of such capacitors may be operated in combination with an appropriate capacitance sensitive test circuit. From the frequency response, the k value may be readily calculated.

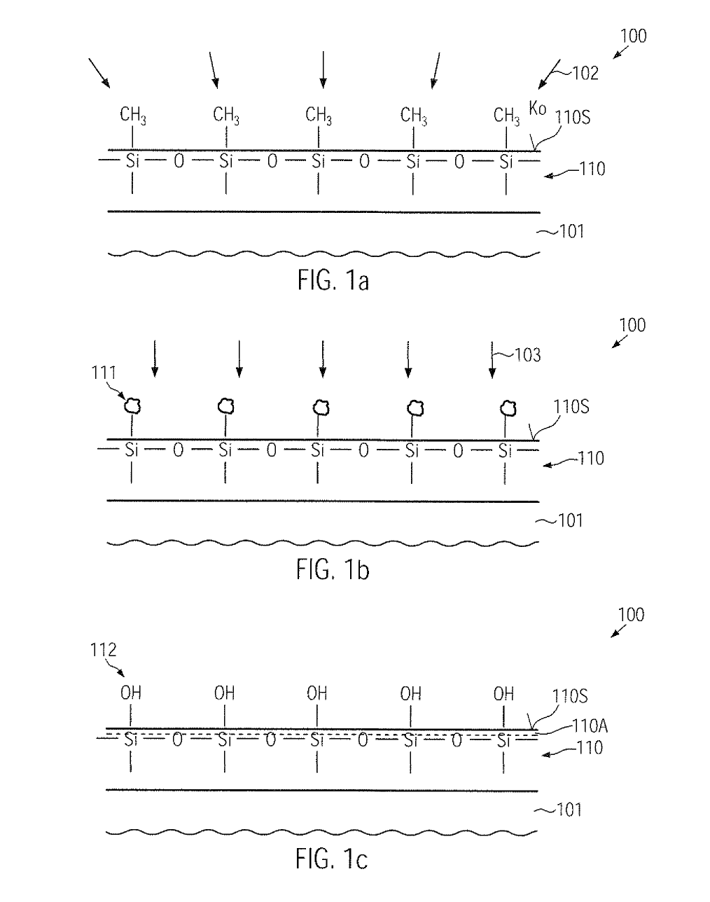

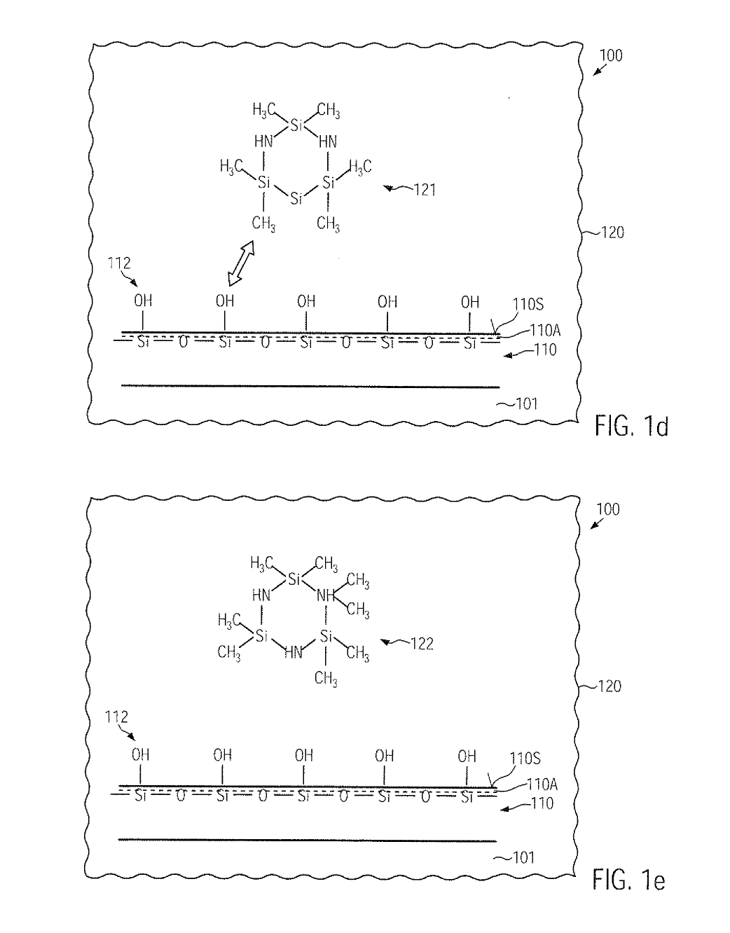

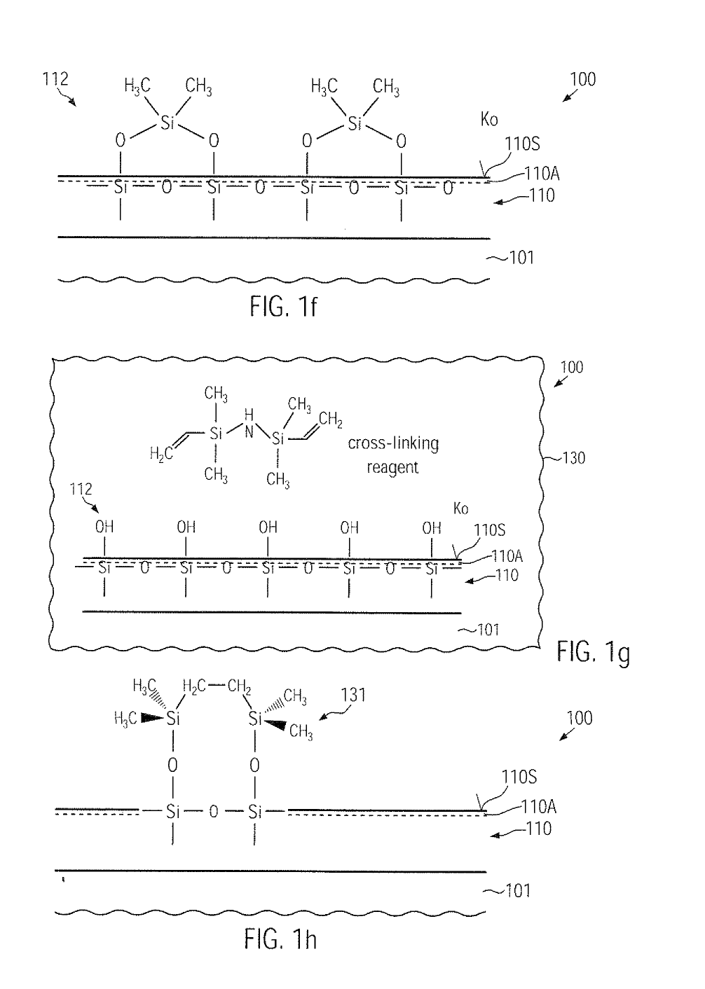

FIG. 1a schematically illustrates a device 100 which may generally be understood as a component comprising a substrate 101, which may represent any appropriate carrier material for forming thereabove a silicon oxide based dielectric layer 110, the dielectric constant of which is to be maintained at approximately 3.0 or less. For example, the device 100 may represent a microstructure device, such as a semiconductor device, in which a low-k value of the layer 110 may be required, for instance, with respect to electrical performance and the like. It should be appreciated that the dielectric layer 110 may have any appropriate thickness, such as several nanometers to several hundred nanometers or even thicker, depending on the specific configuration of the device 100. For example, the material of the layer 110 may be used as an efficient fill material for electrically insulating conductive regions of the device 100. As will be described later on in more detail, the dielectric material 110 may represent an interlayer dielectric material of a semiconductor device, for instance provided in a metallization system thereof. The dielectric material 110 is to be understood as a silicon oxide based material which is to be understood generally as a dielectric material comprising at least silicon and oxygen, wherein other species, such as carbon, hydrogen, nitrogen and the like, also may be incorporated, depending on the desired material characteristics.

The dielectric material 110 may be formed during a deposition process 102, which may represent any appropriate deposition technique, such as spin-on processes, CVD processes, for instance in the form of plasma assisted CVD and thermally activated CVD and the like. For example, a plurality of thermally activated CVD recipes may be applied in which appropriate precursor materials, such as tetramethoxysilane (TMOS) and/or tetraethyloxysilane (TEOS) and the like, may be used for spin-on techniques and CVD processes. Moreover, low pressure plasma enhanced CVD techniques may be applied in which the creation of appropriate precursor ions and radicals may provide significantly enhanced flexibility in selecting an appropriate material composition, since many more reaction paths may be accomplished by providing radicals instead of using thermally activated CVD recipes. Furthermore, as previously indicated, a further reduction of the material density and thus of the dielectric constant may be accomplished by incorporating appropriate species or solvents into the deposition ambient, for instance in the liquid for spin-on techniques or the deposition atmosphere of CVD processes, wherein these components may at least be partially driven out of the material as deposited by a corresponding treatment, for instance, by heating the layer, performing a radiation treatment and the like. Consequently, a nanoporous structure may be obtained in the layer 110, if required, which may result in a significantly reduced dielectric constant, which, however, may also result in an increased surface area at a surface 110S due to the presence of a plurality of cavities at the surface. As a result, after the deposition process 102 and after any post-deposition processes, the layer 110 may have a moderately low dielectric constant K₀, for example in the range of 3.0 to 1.8. which may also be obtained at the surface 110S if an appropriate deposition technique has been used. In this case, the surface 110S may have a substantially hydrophobic nature which may be obtained on the basis of corresponding functional groups, such as a methyl group (CH₃), as illustrated in FIG. 1a. As described above, in some illustrative embodiments, the surface 110S may exhibit a less pronounced hydrophobic nature, for instance due to the presence of a non-negligible amount of silanol groups, which may be caused by specific deposition recipes and the like. In this case, the material in the vicinity of the surface 110S may exhibit a moderately high dielectric constant, which may, however, be reduced by applying process techniques as will be described later on in more detail.

FIG. 1b schematically illustrates the device 100 when exposed to a reactive process ambient 103, which may represent a plasma assisted etch process using etch chemicals, such as chlorine, fluorine, oxygen and the like, as may typically be applied during the processing of microstructure devices. For example, a plurality of plasma assisted etch processes for patterning dielectric materials, such as the layer 110, may be performed on the basis of the above-identified reactive chemicals. Moreover, the patterning of a material layer in microstructure processing may be associated with the provision of a resist mask which may have to be removed on the basis of a plasma assisted reactive ambient or a wet chemical ambient in which oxygen may come into contact with the surface 110S. In other cases, the reactive process ambient 103 may represent a wet chemical cleaning process, as may have typically been performed during microstructure processing at various manufacturing stages in order to remove contaminants or etch byproducts and the like. Consequently, during the exposure to the ambient 103, respective functional groups 111, such as the methyl groups as shown in FIG. 1a, may react with corresponding chemicals, radicals, ions and the like of the ambient 103, thereby resulting in a significant modification of the surface characteristics of the layer 110.

FIG. 1c schematically illustrates the device 100 in a state in which a plurality of silanol groups 112, that is, SI—OH groups, may be incorporated in the surface 1105, for instance as a consequence of the reactive process ambient 103 of FIG. 1b, possibly in combination with the exposure to water and oxygen in the ambient atmosphere, while in other cases the silanol groups 112 may have formed during or after the deposition of the layer 110, without exposing the device 100 to the reactive ambient 103, as previously explained. Due to the polarizable groups 112, the dielectric constant, at least at the surface 1105, i.e., within a small surface layer 110A of the dielectric material 110, may be increased, which may result in an increase of the overall permittivity of the layer 110, thereby altering the overall dielectric behavior. For example, an increased parasitic capacitance may be created due to the presence of the surface layer 110A having the increased dielectric constant.

FIG. 1d schematically illustrates the device 100 when exposed to a process ambient for performing a surface treatment 120, in which at least a significant amount of the polarizable functional groups 112 may be replaced by other functional groups that may contribute to a hydrophobic nature of the surface 110S. In the embodiment shown, the surface treatment 120 may be performed on the basis of cyclic hexamethylcyclotrisilizane, the corresponding composition is illustrated in FIG. 1d, which represents a surface treatment reagent 121 for efficiently removing the functional groups 112 by methyl groups in order to establish or re-establish a desired hydrophobic nature of the surface 110S. The surface treatment 120 may be performed on the basis of any appropriate process conditions, for instance the reagent 121 may be provided as a liquid by selecting an appropriate temperature for applying the reagent 121. In other cases, the reagent 121 may be supplied on the basis of a gaseous ambient or even a plasma assisted ambient, wherein pressure and temperature may be appropriately selected in combination with an appropriate flow rate. It should be appreciated that appropriate process parameters may be readily established by performing corresponding experiments in which the surface 110S may be examined for different process conditions of the ambient 120. For this purpose, for instance, Fourier transformed infrared spectroscopy may provide an efficient mechanism for determining the amount of specific species and the corresponding bondings thereof so that the characteristics of the surface 110S may be correlated with the corresponding process parameters applied. It should be appreciated that Fourier transformed infrared spectroscopy (FTIR) represents a metrology technique which is very sensitive to chemical bonds, wherein the measurement process may be performed on the basis of a moderately broad wavelength range in a short time interval so that statistically relevant measurement data may be obtained within a short time, thereby enabling a precise quantitative analysis of materials and their molecular structure.

FIG. 1e schematically illustrates the semiconductor device 100 wherein the surface treatment 120 may be performed on the basis of cyclic octamethylcyclotetrasilazane, wherein the configuration of the corresponding molecule, indicated as 122, is illustrated in FIG. 1e. Also in this case, the surface treatment reagent 122 may be applied on the basis of any appropriate process conditions, for instance in the form of a gaseous ambient, a plasma ambient, as a liquid and the like. Appropriate process parameters, for instance in terms of plasma power, gas flow rate, pressure, temperature and the like, may be readily established in accordance with the availability of process chambers, PECVD tools and the like. Also in this case, experiments may be performed and the results thereof may be determined on the basis of FTIR analysis techniques, while it should be appreciated that any other analysis technique may also be applied, if considered appropriate. Consequently, also in this case, the polarizable functional groups 112 may be efficiently replaced by methyl groups of the reagent 122, thereby establishing or re-establishing a hydrophobic surface, thereby also providing a desired low dielectric constant.

FIG. 1f schematically illustrates the device 100 after the surface treatment 120 on the basis of the reagents 121 and/or 122 so that the surface layer 110A may have a low dielectric constant, for instance, in the range of 3.0 to 1.8 or even less, which may be comparable to the initial dielectric constant K₀ or which may be even less than the initial dielectric constant, if a certain amount of polarizable functional groups may have been provided at the surface 110S upon depositing the layer 110, as previously explained. As illustrated, the H atom of the silanol group is replaced by a bond to the Si atom. Since the cyclic silanol can be understood as bifunctional molecule, two neighboring H atoms are replaced and are bridged by an Si atom, which in turn is saturated by 2 methyl groups. Hence, a hydrophobic surface is re-established and the further processing of the device 100 may be continued with the desired dielectric behavior, without requiring any further measures, such as the removal of the surface layer 110A, as may typically be applied in some conventional approaches, as discussed above.

FIG. 1g schematically illustrates the device 100 according to further illustrative embodiments in which a treatment 130 may be performed on the surface 110S, i.e., with any silanol groups formed therein, which may be created after deposition of the layer 110. The treatment 130 may be performed on the basis of a process ambient including an appropriate chemical that may have the capability of forming cross-links when reacting with the silanol groups. For example, a plurality of chemicals are available which may polymerize, thereby providing a corresponding cross-linked network at the surface 110S, which may thus contribute to enhanced chemical stability during the further processing of the device 100. For example, silane and any derivatives thereof, such as trimethylsilane, tetramethylsilane, tetramethyldisilazane and the like, in combination with a functional group, such as vinyl groups, phenyl groups and the like, may be efficiently used during the treatment 130, thereby obtaining a polymerized surface layer. By way of example, the following chemicals may be efficiently used for obtaining the desired cross-linking behavior: Divinyltetramethyldisilazane (Cl₂C₈H₁₉N), tetravinyltetramethylcyclotetrasilazane (Cl₄Cl₂H₂₈N₄), trivyniltrimethylcyclotrisilazane (SI₃C₉H₂₁N₃), diphenyl-tetramethyldisilazane (Cl₂C₁₈H₂₃N), tetraphenyl-tetramethyldisilazane (Cl₂C₂₆H₂₇N), cianopropylmethylsilazane (CIC₅H₁₀N₂), tetraethyl-tetramethylcyclotetrasilazane (Cl₄Cl₂H₃₆N₄) and the like.

In some illustrative embodiments, the treatment 130 for forming a cross-linked surface may be performed in combination with the treatment 120 (FIGS. 1d-1e), wherein the corresponding chemical having the cross-linking capability may be supplied during the treatment 120.

The silanol groups may react with the vinyl silanes. In a following stage or most likely in situ with the silanol capping, the vinyl groups tend to polymerize and result in the formation of C—C bridges between the Si atoms, which have replaced the H atom of the silanol group. This is also possible if the silanol groups are not neighbors, if appropriate vinyl or other groups tending to polymerization are used.

FIG. 1h schematically illustrates the device 100 with a cross-linked species 131, thereby imparting superior chemical stability to the surface layer 110A. Consequently, a low-k value in combination with superior chemical stability may be provided on the basis of the species 131, thereby enhancing the further processing of the device 100. It should be appreciated that the polymerized nature of the surface layer 110A may be efficiently determined on the basis of FTIR analysis techniques, which may also be used for establishing appropriate process conditions and chemicals for performing the treatment 130 as shown in FIG. 1g.

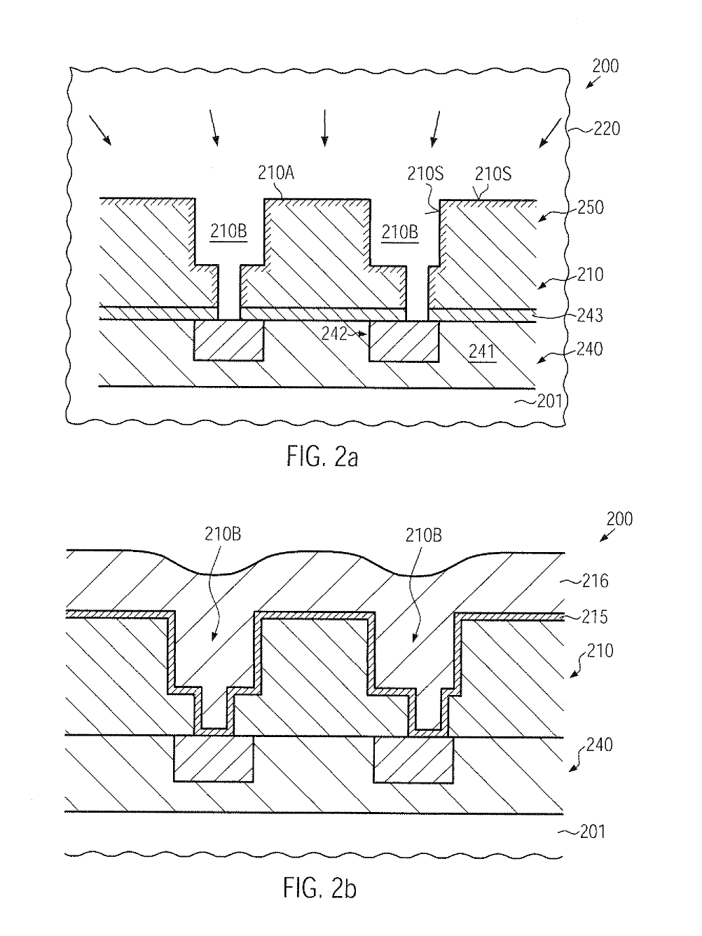

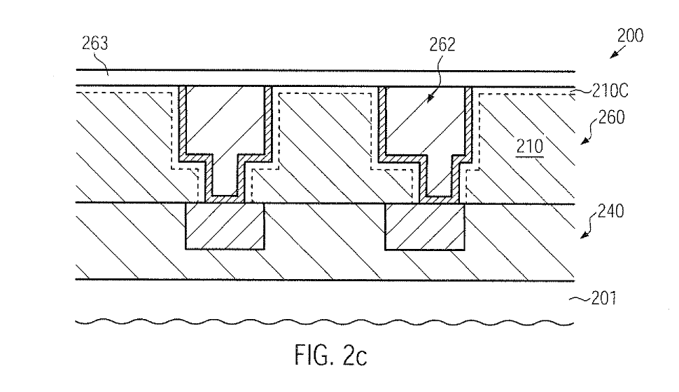

With reference to FIGS. 2a-2c, further illustrative embodiments will now be described in which one or more process techniques described above may be applied to a manufacturing process for forming a microstructure device, such as a semiconductor device.

FIG. 2a schematically illustrates a cross-sectional view of a microstructure device 200, which may represent any appropriate device having formed therein micromechanical, microoptical, microelectronic, or any other device features requiring a silicon oxide based low-k dielectric material. In one illustrative embodiment, the microstructure device 200 may represent a semiconductor device comprising a substrate 201, above which may be formed one or more device levels, at least one of which may include a silicon oxide based low-k dielectric material with a k of approximately 3.0 or less. For example, a metallization system 250 may be provided which may comprise a first metallization layer 240, which may represent a dielectric material 241 of any appropriate composition in which conductive regions 242 may be embedded, such as lines, contact areas and the like, depending on the specific configuration of the device 200. For example, the conductive regions 242 may represent metal lines or metal regions of the metallization system 250. Furthermore, an etch stop layer 243 may be formed on the dielectric material 241 and the conductive region 242. Furthermore, a dielectric layer 210 may be formed above the etch stop layer 243 and may comprise openings 210B, which may represent a trench and/or a via opening, when the layer 210 may represent the dielectric material of a metallization layer of the system 250. In the embodiment shown in FIG. 2a, the dielectric layer 210 may represent a silicon oxide based dielectric material, which may substantially continuously extend down to the etch stop layer 243. In other cases, only a portion of the dielectric layer 210 may be provided as a silicon oxide based material, depending on the overall configuration of the device 200. For example, the layer 210 may have similar characteristics as previously described with reference to the dielectric layer 110 of the device 100. Thus, the thickness of the layer 210 as well as the size and position of the openings 210B may be appropriately selected in accordance with the design rules of the device 200. For example, a lateral dimension of the openings 210B may range from several tenths nm and more. Furthermore, in the manufacturing stage shown, the dielectric layer 210 may have exposed surface areas 210S and may also have a modified or damaged surface layer 210A, which may contain a non-acceptable amount of polarizable functional groups, as also previously explained with reference to the device 100. For example, a thickness of the modified surface layer 210A may be approximately 20 nm to several nm.

The microstructure device 200 may be formed on the basis of the following process techniques. After providing any device features such as transistors, capacitors and the like in and above the substrate 201, for instance on the basis of an appropriate semiconductor layer, the layers 240 and 210 may be formed in accordance with established process techniques. For instance, the layer 240 may be formed by depositing the dielectric material 241 and patterning the same so as to subsequently fill in an appropriate conductive material in order to provide the regions 242. It should be appreciated that similar process techniques may be applied for forming the layer 240, when representing a metallization layer formed on the basis of a silicon oxide based low-k dielectric material, as may also be applied when forming the dielectric material 210. Thereafter, the etch stop material 243 may be provided on the basis of any appropriate deposition technique followed by the deposition of the layer 210, which may be accomplished on the basis of process techniques as previously explained with reference to FIG. 1a when referring to the layer 110. It should be appreciated, however, that, in addition to the silicon oxide based material, other materials may also be deposited, if required. Thereafter, any appropriate patterning strategy may be applied, which may involve lithography and anisotropic etch techniques, possibly in combination with additional wet chemical etch strategies in order to obtain the openings 210B. Consequently, during exposure to a reactive ambient during this process sequence, the damaged surface layer 210A may be created, thereby significantly reducing the hydrophobic nature and thus increasing the dielectric constant of the surface layer 210A. Consequently, the device 200 may be exposed to a surface treatment 220 in order to substantially re-establish a desired hydrophobic nature of the surface 210S. For this purpose, the treatment 220 may be performed on the basis of the surface reagent as previously described above with respect to the surface treatment 120. In further illustrative embodiments, the treatment 220 may also include a treatment in order to provide a polymerized surface layer, which may be accomplished on the basis of the techniques previously described with reference to the treatment 130.

FIG. 2b schematically illustrates the microstructure device 200 in a further advanced manufacturing stage. As illustrated, a conductive metal 216, for instance a copper-based material and the like, may be formed in the openings 210B and above the dielectric material 210, possibly in combination with a conductive barrier material 215, such as tantalum, tantalum nitride and the like. The layers 215, 216 may be formed on the basis of any appropriate manufacturing technique, as is also previously explained.

FIG. 2c schematically illustrates the microstructure device 200 in a further advanced manufacturing stage. As illustrated, a metallization layer 260 may comprise the dielectric layer 210 and corresponding metal regions 262 formed therein on the basis of the openings 210b (FIG. 2a) and the material layers 215, 216 (FIG. 2b). Furthermore, an etch stop or capping layer 263 may be formed on the dielectric material 210 and the metal regions 262. Furthermore, in the embodiment shown, an interface layer 210C may be provided which may connect to the etch stop or capping layer 263 and which may also connect to the metal regions 262. The interface layer 210C may have a moderately low dielectric constant and, in the embodiment shown, may have a polymerized structure, as is for instance explained with reference to FIG. 1h.

As a result, the present disclosure provides methods and microstructure devices in which silicon oxide based dielectric materials may have a reduced dielectric constant of approximately 3.0 and less at a surface area or interface area, which may be accomplished by performing a surface treatment and/or initiating a cross-linking at the surface or interface. Consequently, in some illustrative embodiments, a low-k status or hydrophobic status of damaged surface areas may be re-established after exposure to a reactive process ambient, which may typically result in a significant increase of the relative permittivity, in particular when nanoporous dielectric films are considered.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

What is claimed:

1. A method of forming a low-k dielectric material above a substrate, the method comprising:
forming a silicon and oxygen containing dielectric material above said substrate; and
performing a surface treatment on at least a portion of a surface of said silicon and oxygen containing dielectric material on the basis of at least one of hexamethylcyclotrisilizane and octamethylcyclotetrasilazane so as to reduce a dielectric constant at least at said portion of the silicon and oxygen containing dielectric material.

2. The method of claim 1, wherein said silicon and oxygen containing dielectric material is formed so as to have a dielectric constant of approximately 3.0 or less and wherein said method further comprises exposing said at least a portion of a surface of said silicon and oxygen containing dielectric material to a reactive process ambient prior to performing said surface treatment.

3. The method of claim 1, wherein said silicon and oxygen containing dielectric material is formed so as to have a porous structure.

4. The method of claim 1, wherein said at least one of hexamethylcyclotrisilizane and octamethylcyclotetrasilazane is applied as a liquid when performing said surface treatment.

5. The method of claim 1, wherein said at least one of hexamethylcyclotrisilizane and octamethylcyclotetrasilazane is applied as a vapor when performing said surface treatment.

6. The method of claim 1, wherein performing said surface treatment comprises establishing a plasma ambient on the basis of said at least one of hexamethylcyclotrisilizane and octamethylcyclotetrasilazane.

7. The method of claim 2, wherein exposing said at least a portion of said silicon and oxygen containing dielectric material to a reactive ambient comprises forming an opening in said silicon and oxygen containing dielectric material on the basis of a plasma assisted etch ambient.

8. The method of claim 2, wherein exposing said at least a portion of said silicon and oxygen containing dielectric material to a reactive ambient comprises performing a wet chemical cleaning process after patterning said silicon and oxygen containing dielectric material on the basis of a plasma assisted etch ambient.

9. The method of claim 1, further comprising initiating one of a di-merization and a polymerization reaction by supplying one or more chemical reagents to said at least a portion of the surface so as to increase chemical stability of said at least a portion of the surface.

10. The method of claim 9, wherein said one or more chemical reagents are supplied when performing said surface treatment.

11. The method of claim 9, wherein said one or more chemical reagents are supplied after performing said surface treatment.

12. The method of claim 9, wherein said one or more chemical reagents comprise at least one of silane, tri-methyl silane, tetra-methyl silane and tetramethyldisilazane in combination with one or more functional groups.

13. The method of claim 12, wherein said one or more functional groups comprise a vinyl group.

14. The method of claim 1, wherein said silicon and oxygen containing dielectric material is a dielectric material of a microstructure device.

15. The method of claim 14, wherein said silicon and oxygen containing dielectric material is a dielectric material of a metallization system of a semiconductor device.

16. A method of forming a low-k dielectric material in a microstructure device, the method comprising:
forming a silicon and oxygen containing dielectric material above a substrate; and
performing a treatment for forming cross-links in said surface by supplying one or more chemical reagents to said surface to react with polar Si—OH groups contained in said surface.

17. The method of claim 16, wherein said one or more chemical reagents comprise at least one of silane, tri-methyl silane, tetra-methyl silane and tetramethyldisilazane in combination with a functional group for initiating one of di-merization and polymerization.

18. The method of claim 17, wherein said functional groups comprise a vinyl group.

19. The method of claim 16, further comprising treating said silicon and oxygen containing dielectric material layer in a reactive process ambient resulting in the creation of said polar Si—OH groups.

20. A microstructure device, comprising:
a low-k dielectric material formed above a substrate, said low k-dielectric material comprising silicon and oxygen and a hydrophobic interface portion with a polymerized surface structure.

21. The microstructure device of claim 20, wherein said hydrophobic interface portion comprises at least one of silane and derivatives thereof.

22. The microstructure device of claim 21, wherein said hydrophobic interface portion comprises vinyl groups.

23. The microstructure device of claim 20, further comprising metal regions embedded in said low-k dielectric material and connecting to said interface portion.

24. The microstructure device of claim 20, wherein said low-k dielectric material has a porous structure.
